(19) United States
(12) Patent Application Publication
(10) Pub. No.: US 2026/0362677 A1
(43) Pub. Date: Nov. 12, 2026

(54) SEMICONDUCTOR MEMORY DEVICE INCLUDING HORIZONTAL WORD LINES

(71) Applicant: Samsung Electronics Co., Ltd., Suwon-si (KR)

(72) Inventors: Taejin Park, Suwon-si (KR); Daesun Kim, Suwon-si (KR); Sungsoo Yim, Suwon-si (KR)

(73) Assignee: Samsung Electronics Co., Ltd., Suwon-si (KR)

(21) Appl. No.: 19/669,326

(22) Filed: May 6, 2026

(30) Foreign Application Priority Data
May 12, 2025 (KR) 10-2025-0061461

(51) Int. Cl. H10B 12/00

(52) U.S. Cl. CPC H10B 12/315; H10B 12/05

(57) ABSTRACT

A semiconductor memory device includes active patterns arranged apart from one another in first and second substantially horizontal directions, and arranged in a matrix form of rows and columns, landing pads respectively arranged on the active patterns and apart from one another in the first and second substantially horizontal directions, wherein the landing pads include the landing pads, of a first group, shifted in a first reverse substantially horizontal direction on the active patterns forming one column among the active patterns and the landing pads, of a second group, shifted in the first substantially horizontal direction; lower electrodes respectively arranged on the landing pads and apart from one another in the first and second substantially horizontal directions, and word lines respectively arranged on one side of the active patterns, apart from one another in the first substantially horizontal direction, and extending in the second substantially horizontal direction.

### CROSS-REFERENCE TO RELATED APPLICATIONS

This present application claims priority to and the benefit under 35 U.S.C. § 119(a)-(d) of Korean Patent Application No. 10-2025-0061461, filed on May 12, 2025, in the Korean Intellectual Property office, the entire disclosure of which is incorporated herein by reference.

### FIELD

The disclosed concepts relate to a semiconductor memory device, and more particularly, to a semiconductor memory device including a vertical channel transistor.

### BACKGROUND

It may be difficult to improve the degree of integration of semiconductor memory devices having two-dimensional transistors or planar transistors, by reducing the area occupied by memory cells. Accordingly, a semiconductor memory device having a three-dimensional transistor or a vertical channel transistor has been proposed.

### SUMMARY

The disclosed concepts provide a semiconductor memory device including vertical channel transistors and at the same time, capable of improving leakage occurrence between data storage elements arranged adjacent to one another in one row.

According to aspects of the disclosed concepts, there is provided a semiconductor memory device including a plurality of active patterns arranged apart from one another in a first substantially horizontal direction and in a second substantially horizontal direction perpendicular to the first substantially horizontal direction, and arranged in a matrix form of rows and columns, a plurality of landing pads respectively arranged on the plurality of active patterns and apart from one another in the first and second substantially horizontal directions, wherein the plurality of landing pads include the landing pads, of a first group, shifted in a first reverse substantially horizontal direction on the active patterns forming one column among the plurality of active patterns, and the landing pads, of a second group, shifted in the first substantially horizontal direction, a plurality of lower electrodes respectively arranged on the plurality of landing pads and apart from one another in the first and second substantially horizontal directions, and a plurality of word lines respectively arranged on one side of the plurality of active patterns, apart from one another in the first substantially horizontal direction, and extending in the second substantially horizontal direction.

The plurality of word lines may include odd-numbered word lines and even-numbered word lines in the first substantially horizontal direction, and the odd-numbered word lines and the even-numbered word lines are alternately connected to the landing pads of the first group and the landing pads of the second group in one column in the second substantially horizontal direction, respectively.

According to aspects of the disclosed concepts, there is provided a semiconductor memory device including a plurality of active patterns arranged apart from one another in a first substantially horizontal direction and in a second substantially horizontal direction perpendicular to the first substantially horizontal direction, and arranged in a matrix form of rows and columns, a plurality of landing pads arranged on the active patterns and apart from one another in the first and second substantially horizontal directions, wherein the landing pads include first landing pads on the active patterns, second landing pads of a first group shifted in a first reverse substantially horizontal direction on the first landing pads arranged on the active patterns forming one column among the plurality of active patterns, and second landing pads of a second group shifted in the first substantially horizontal direction, a plurality of lower electrodes respectively arranged on the second landing pads of the first group and the second landing pads of the second group, and apart from one another in the first and second direction, and a plurality of word lines respectively arranged on one side of the plurality of active patterns, apart from one another in the first substantially horizontal direction, and extending in the second substantially horizontal direction.

The plurality of word lines may include odd-numbered word lines and even-numbered word lines in the first substantially horizontal direction, and the odd-numbered word lines and the even-numbered word lines are alternately connected to the second landing pads of the first group and the second landing pads of the second group in one column in the second substantially horizontal direction, respectively.

According to aspects of the disclosed concepts, there is provided a semiconductor memory device including a plurality of bit lines extending in a first substantially horizontal direction and apart from one another in a second substantially horizontal direction perpendicular to the first substantially horizontal direction, a plurality of word lines on the bit lines, wherein the word lines extend in the second substantially horizontal direction and are apart from one another in the first substantially horizontal direction, a plurality of active patterns apart from one another on one side of the word lines on the bit lines in the first substantially horizontal direction and the second substantially horizontal direction, and arranged in a matrix form of rows and columns, a plurality of landing pads arranged on the active patterns and apart from one another in the first and second substantially horizontal directions, wherein the landing pads include first landing pads on the active patterns, second landing pads of a first group shifted in a first reverse substantially horizontal direction on the first landing pads arranged on the active patterns forming one column among the plurality of active patterns, and second landing pads of a second group shifted in the first substantially horizontal direction, a plurality of lower electrodes respectively arranged on the second landing pads of the first group and the second landing pads of the second group, and apart from one another in the first and second direction, and a plurality of word lines respectively arranged on one side of the plurality of active patterns, apart from one another in the first substantially horizontal direction, and extending in the second substantially horizontal direction.

A lower surface of each of the plurality of lower electrodes partially and vertically overlaps the corresponding second landing pad among the plurality of second landing pads, but does not vertically overlap, that is, is free from the corresponding active pattern among the plurality of active patterns. The plurality of word lines may include odd-numbered word lines and even-numbered word lines in the first substantially horizontal direction, and the odd-numbered word lines and the even-numbered word lines are alternately connected to the second landing pads of the first group and the second landing pads of the second group in one column in the second substantially horizontal direction, respectively.

According to aspects of the disclosed concepts, there is provided a method of manufacturing a semiconductor memory device including forming a plurality of active patterns arranged in a matrix form of rows and columns, wherein the active patterns are apart from one another in a first substantially horizontal direction and a second substantially horizontal direction perpendicular to the first substantially horizontal direction, forming a plurality of gate insulating layers apart from one another in the first substantially horizontal direction on one side of the active patterns and extending in the second substantially horizontal direction, and word lines on the gate insulating layers, forming a plurality of first landing pads apart from one another in the first and second substantially horizontal directions on a first surface of the active patterns, forming a second landing pads on the first landing pads, wherein the second landing pads include the second landing pads of a first group shifted in a first reverse substantially horizontal direction and the second landing pads of a second group shifted in the first substantially horizontal direction on the first landing pads arranged on the active patterns forming one column among the plurality of active patterns, and forming a plurality of lower electrodes respectively arranged on the second landing pads of the first group and the second landing pads of the second group, and apart from one another in the first and second substantially horizontal direction.

The plurality of word lines may include odd-numbered word lines and even-numbered word lines in the first substantially horizontal direction, and the odd-numbered word lines and the even-numbered word lines are alternately connected to the second landing pads of the first group and the second landing pads of the second group in one column in the second substantially horizontal direction, respectively.

In embodiments, the odd-numbered word lines may be electrically connected to odd-numbered data storage elements in one column in the second substantially horizontal direction, and the even-numbered word lines are electrically connected to even-numbered data storage elements in one column in the second substantially horizontal direction.

In embodiments, the plurality of lower electrodes may include the lower electrodes of a first group and the lower electrodes of a second group alternately arranged in the second substantially horizontal direction, wherein the lower electrodes of the first group are connected to one of the odd-numbered word lines, and the lower electrodes of the second group are connected to one of the even-numbered word lines.

In embodiments, the plurality of lower electrodes may include the lower electrodes of a first group and the lower electrodes of a second group alternately arranged in the second substantially horizontal direction, wherein the lower electrodes of the first group are connected to one of the even-numbered word lines, and the lower electrodes of the second group are connected to one of the odd-numbered word lines.

In embodiments, the word lines may constitute gate electrodes, and the active patterns, the gate insulating layers, and the gate electrodes form vertical channel transistors.

In embodiments, a first source/drain region and a second source/drain region may be formed in each of the active patterns in a substantially vertical direction, and a channel region is formed between the first source/drain region and the second source/drain region.

In embodiments, the active patterns may include a first active pattern and a second active pattern alternately arranged in the first substantially horizontal direction, and back gate insulating layers and back gate electrodes extending in the second substantially horizontal direction between the first active pattern and the second active pattern.

In embodiments, back gate insulating layers and back gate electrodes extending in the second substantially horizontal direction may be formed between the word lines in the first substantially horizontal direction.

In embodiments, a back gate electrode extending in the second substantially horizontal direction may be further formed between one of the odd-numbered word lines and the even-numbered word lines, which are adjacent to one another.

In embodiments, the second landing pad may include first extension landing pads extending in a first reverse substantially horizontal direction and second extension landing pads extending in the first substantially horizontal direction on the active patterns in the one column.

In embodiments, a plurality of bit lines extending in the first substantially horizontal direction and apart from one another in the second substantially horizontal direction on a second surface facing the first surface of the active patterns may be further formed.

In embodiments, a plurality of contact patterns apart from one another in the first and second substantially horizontal direction may be formed on the first surface of the active patterns.

### BRIEF DESCRIPTION OF THE DRAWINGS

Embodiments of the disclosed concepts will be more clearly understood from the following detailed description taken in conjunction with the accompanying drawings in which:

FIG. 1 is a block diagram of a semiconductor memory device according to embodiments;

FIG. 2 is a schematic perspective view of a semiconductor memory device according to embodiments;

FIGS. 3 through 6B are layout diagrams for describing a semiconductor memory device according to embodiments;

FIGS. 7A and 7B are diagrams of relations between watch lines and data storage elements of a semiconductor memory device, according to embodiments;

FIGS. 8A and 8B are cross-sectional views of the layout of 6A taken along lines A-A′ and B-B′, respectively;

FIG. 8C is an enlarged view of a vertical channel transistor in FIGS. 8A and 8B; and

FIGS. 9 through 28 are diagrams for describing a method of manufacturing a semiconductor memory device, according to embodiments.

### DETAILED DESCRIPTION

Below, the disclosed concepts will now be described more fully with reference to the accompanying drawings, in which example embodiments of the disclosed concepts are shown. The following embodiments of the disclosed concepts may be implemented by any one of them, and the following embodiments may be implemented by combining one or more of them. Thus, the technical idea of the disclosed concepts is not limited to only one embodiment. In the embodiments, an order, such as first, second, and nth, may be intended to facilitate descriptions, and the disclosed concepts are not limited to the order.

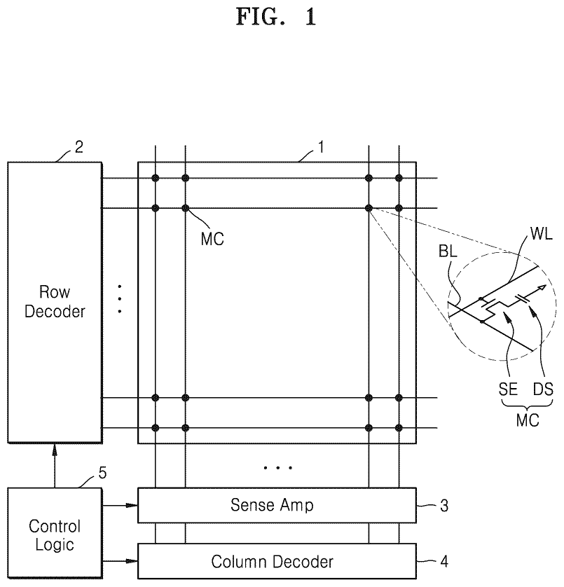

FIG. 1 is a block diagram of a semiconductor memory device according to embodiments.

The semiconductor memory device may include a memory cell array 1, a row decoder 2, a sense amplifier 3, a column decoder 4, and a control logic 5. The memory cell array 1 may include a plurality of memory cells MCs arranged two-dimensionally or three-dimensionally.

Each of the memory cells MC may be connected between a word line WL and a bit line BL crossing one another. Each of the memory cells MC may include a selection element SE and a data storage element DS. The selection element SE may be electrically connected to the data storage element DS in series.

The selection element SE may be connected between the data storage element DS and the word line WL. The data storage element DS may be connected to the bit line BL via the selection element SE. The selection element SE may include a field effect transistor FET. The data storage element DS may be implemented as a capacitor including a lower electrode, a capacitor dielectric layer, and an upper electrode.

For example, the selection element SE may include a vertical channel transistor VCT. A gate electrode of the vertical channel transistor VCT may be connected to the word line WL, and a drain terminal and a source terminal of the vertical channel transistor VCT may be connected to the bit line BL and the data storage element DS, respectively.

The row decoder 2 may decode an address input from the outside, and select any one of the word lines WL of the memory cell array 1. The address decoded by the row decoder 2 may be provided to a row driver (not illustrated). The row driver (not illustrated) may provide a certain voltage to each of the selected word line WL and unselected word lines WL, in response to the control signal of the control logic 5.

The sense amplifier 3 may detect and amplify a voltage difference between the bit line BL selected according to the decoded address by the column decoder 4 and a reference bit line, and output the detected and amplified voltage difference. The column decoder 4 may provide a data transmission path between the sense amplifier 3 and an external device (for example, a memory controller). The column decoder 4 may decode an address input from the outside, and select any one of the bit lines BL. The control logic 5 may generate control signals for controlling operations of writing or reading data to the memory cell array 1.

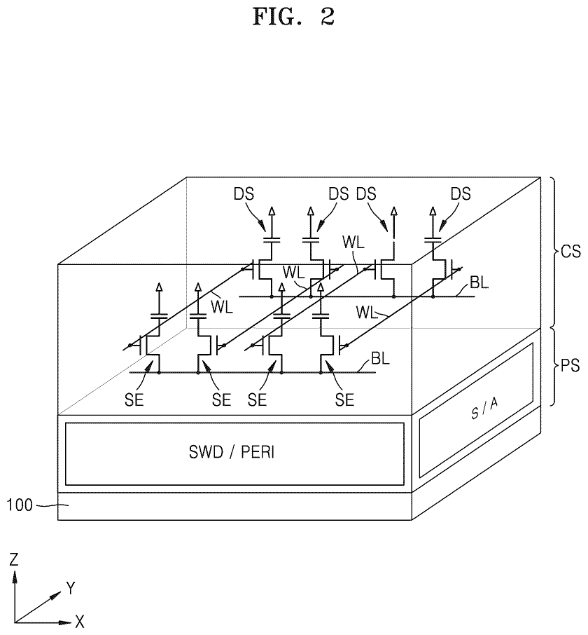

FIG. 2 is a schematic perspective view of the semiconductor memory device according to embodiments.

The semiconductor memory device may include a periphery circuit structure PS arranged on a substrate 100, and a cell array structure CS arranged on the periphery circuit structure PS. The periphery circuit structure PS may include a core circuit and a periphery circuit PERI formed on the substrate 100.

The core circuit and the periphery circuit PERI may include the row decoders and the column decoder (2 and 4 in FIG. 1, respectively) described above, the sense amplifier S/A (3 in FIG. 1), the control logics (5 in FIG. 1), and a source word line driver circuit SWD. The periphery circuit structure PS may be provided between the substrate 100 and the cell array structure CS in a vertical direction (Z direction) perpendicular to an upper surface of the substrate 100.

The cell array structure CS may include the bit lines BL and the word lines WL, and the memory cells (MC in FIG. 1) therebetween. The memory cells (MC in FIG. 1) may be two-dimensionally or three-dimensionally arranged on an extended plane in a first horizontal direction (X direction) and a second horizontal direction (Y direction) parallel to the upper surface of the substrate 100 and crossing one another.

Each of the memory cells (MC in FIG. 1) may, as described above, include the selection element SE and the data storage element DS. Each of the memory cells (MC in FIG. 1) may include the vertical channel transistor VCT as the selection element SE. The vertical channel transistor VCT may be referred to as a structure in which a channel length extends in the vertical direction (Z direction) perpendicular to the upper surface of the substrate. In addition, each of the memory cells (MC in FIG. 1) may, as a data storage element DS, constitute a capacitor including a lower electrode, a capacitor dielectric layer, and an upper electrode.

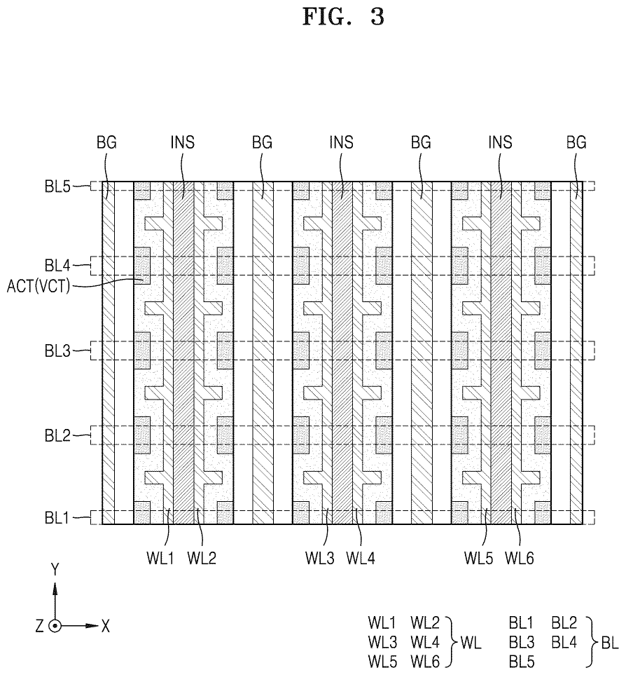

FIGS. 3 through 6B are layout diagrams for describing the semiconductor memory device according to embodiments.

Referring to FIG. 3, the semiconductor memory device may include a plurality of active patterns ACT. The plurality of vertical channel transistors VCT may be respectively arranged on the active patterns ACT. The active patterns ACT, that is, the vertical channel transistors VCT, may be arranged apart from one another in the first horizontal direction (X direction) and the second horizontal direction (Y direction) perpendicular to the first horizontal direction (X direction). The active patterns ACT, that is, the vertical channel transistors VCT, may be arranged in the form of a matrix having rows and columns.

The semiconductor memory device may include a plurality of word lines WL. The word lines WL may be arranged on one side of the active patterns ACT, that is, the vertical channel transistors VCT. The active patterns ACT, that is, the vertical channel transistors VCT, may be arranged outside each of the word lines WL in the first horizontal direction (X direction).

The word lines WL may be apart from one another in the first horizontal direction (X direction), and extend in the second horizontal direction (Y direction). An insulation region INS extending in the second horizontal direction (Y direction) may be between the word lines WL. The insulation region INS may include an interlayer insulating layer or a gate capping layer.

The word lines WL may illustrate, as examples, first through sixth word lines WL1 through WL6. The first word line WL1, the third word line WL3, and the fifth word line WL5 may be odd-numbered word lines WL in the first horizontal direction (X direction). The second word line WL2, the fourth word line WL4, and the sixth word line WL6 may be even-numbered word lines WL in the first horizontal direction (X direction).

The first word line WL1 and the second word line WL2 may be arranged to face one another in the first horizontal direction (X direction). The third word line WL3 and the fourth word line WL4 may be arranged to face one another in the first horizontal direction (X direction). The fifth word line WL5 and the sixth word line WL6 may be arranged to face one another in the first horizontal direction (X direction).

The semiconductor memory device may further include a plurality of back gate electrodes BG ((or back gate lines). The back gate electrodes BG may extend in the second horizontal direction (Y direction). The back gate electrodes BG may be formed to extend in the second horizontal direction (Y direction) between the active patterns ACT adjacent to one another between the word lines WL in the first horizontal direction (X direction), that is, between the vertical channel transistors VCT.

The active patterns ACT, that is, the vertical channel transistors VCT, may be arranged outside each of the word lines WL in the first horizontal direction (X direction). Back gate electrodes BG extending in the second horizontal direction (Y direction) may be further arranged between the active patterns ACT arranged outside each of the word lines WL, that is, between the vertical channel transistors VCT.

The back gate electrodes BG may be arranged between the even-numbered word lines WL and the odd-numbered word lines WL adjacent to one another in the first horizontal direction (X direction). For example, the back gate electrodes BG may be arranged to extend between the second word line WL2 and the third word line WL3, and between the fourth word line WL4 and the fifth word line WL5 in the second horizontal direction (Y direction).

The semiconductor memory device may include the plurality of word lines WL. The bit lines BL may be arranged below the active patterns ACT, that is, below the vertical channel transistors VCT and the word lines WL. The bit lines BL may extend in the first horizontal direction (X direction). The bit lines BL may be arranged apart from one another in the second horizontal direction (Y direction). The bit lines BL may illustrate, as examples, the first through fifth bit lines BL1 through BL5.

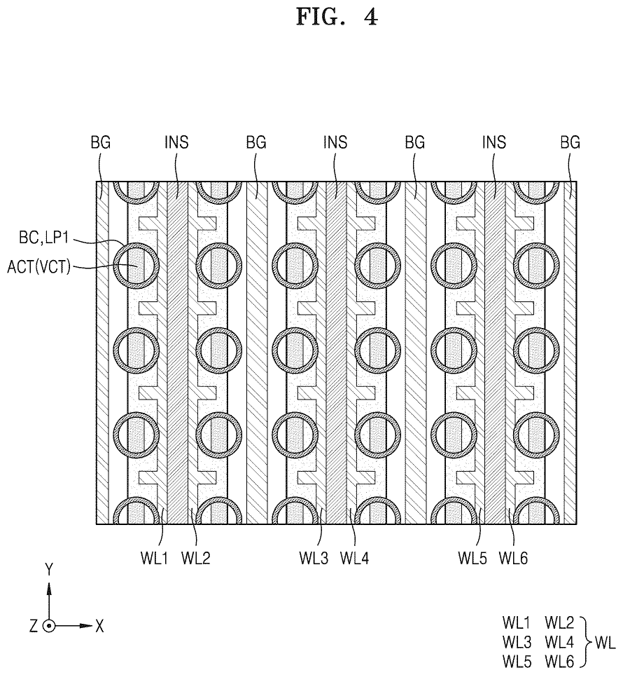

Referring to FIG. 4, the semiconductor memory device may include a plurality of contact patterns BC and a plurality of first landing pads LP1. The contact patterns BC and the first landing pads LP1 may overlap one another in a plan view.

The contact patterns BC and the first landing pads LP1 may be arranged on the active patterns ACT, that is, on the vertical channel transistors VCT. The contact patterns BC and the first landing pads LP1 may be apart from one another in the first horizontal direction (X direction) and the second horizontal direction (Y direction), and may be arranged in the form of a matrix having rows and columns. The contact patterns BC and the first landing pads LP1 may be arranged aligned with one another in the first horizontal direction (X direction) and the second horizontal direction (Y direction), respectively.

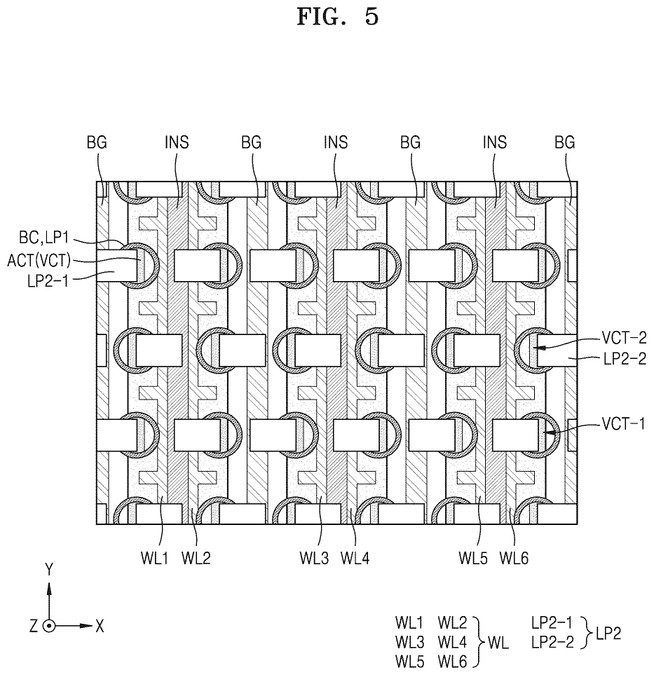

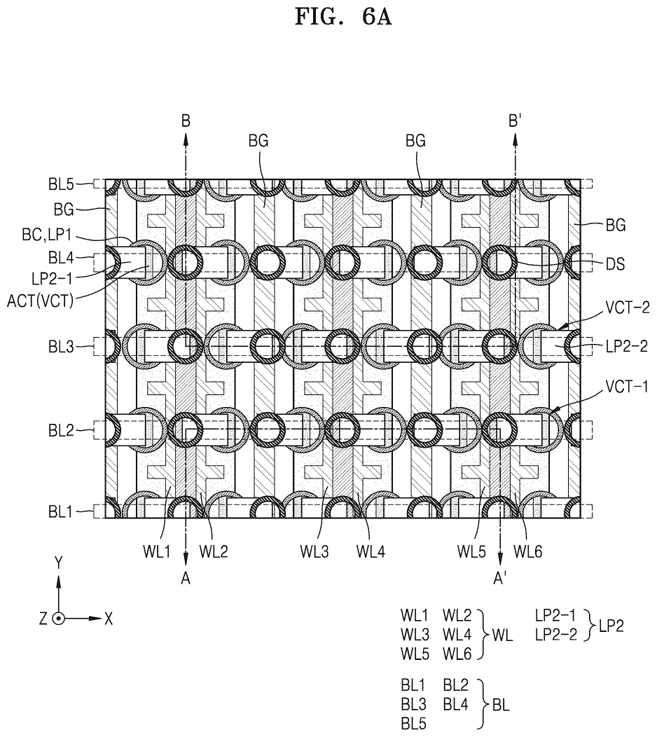

Referring to FIG. 5, the semiconductor memory device may include first and second landing pads LP2 (LP2-1 and LP2-2) extending in a first reverse horizontal direction (−X direction) or the first horizontal direction (X direction) on the first landing pads LP1. The second landing pads LP2 (LP2-1 and LP2-2) may be alternately shifted and arranged in the first reverse horizontal direction (−X direction) and the first horizontal direction (X direction) in one row of the active patterns ACT in one column, that is, on the vertical channel transistors VCT. The second landing pads LP2 (LP2-1 and LP2-2) may be arranged in a zigzag shape in one row of the active patterns ACT, that is, the vertical channel transistors VCT.

The second landing pads LP2 (LP2-1 and LP2-2) may include first extension landing pads LP2-1 extending in the first reverse horizontal direction (−X direction) and second extension landing pads LP2-2 extending in the first horizontal direction (X direction) in one row of active patterns ACT, that is, on the vertical channel transistors VCT.

The first extension landing pads LP2-1 may include landing pads of a first group shifted in the first reverse horizontal direction (−X direction) on the active patterns ACT forming one column among the plurality of active patterns ACT. The second extension landing pads LP2-2 may include landing pads of a second group shifted in the first horizontal direction (X direction) on the active patterns ACT forming one column among the plurality of active patterns ACT.

The first extension landing pads LP2-1 and the second extension landing pads LP2-2 may be alternately arranged on the active patterns ACT in one row, that is, on the vertical channel transistors VCT. The first extension landing pads LP2-1 may be respectively arranged on first vertical channel transistors VCT-1. The second extension landing pads LP2-2 may be respectively arranged on second vertical channel transistors VCT-2. The first vertical channel transistors VCT-1 and the second vertical channel transistors VCT-2 may constitute the vertical channel transistors VCT.

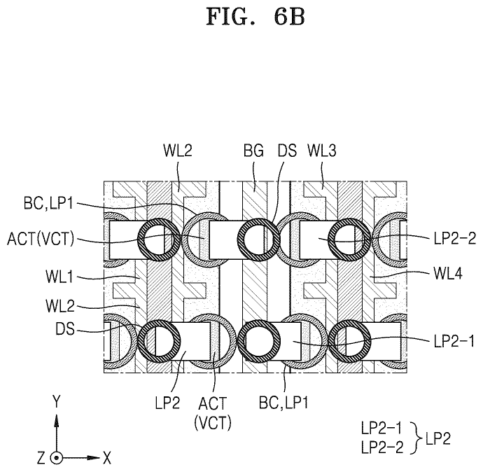

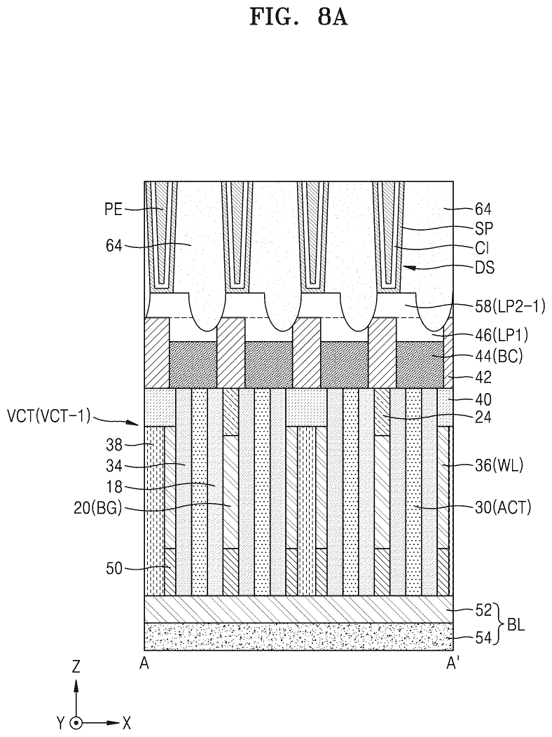

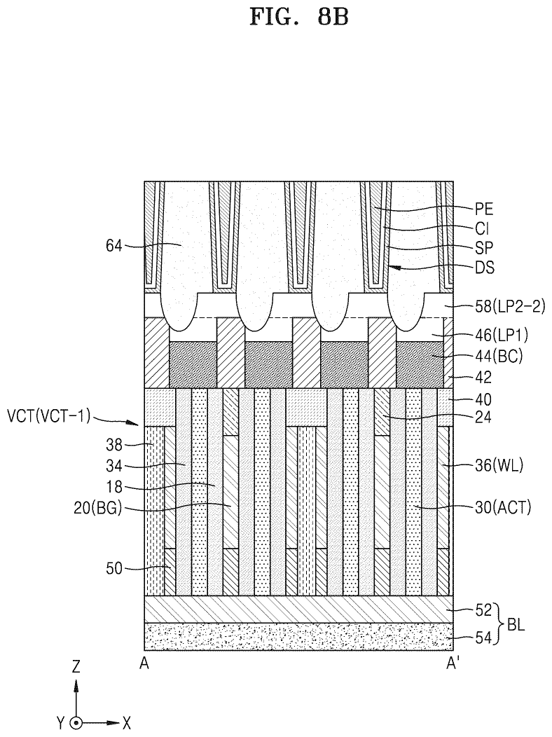

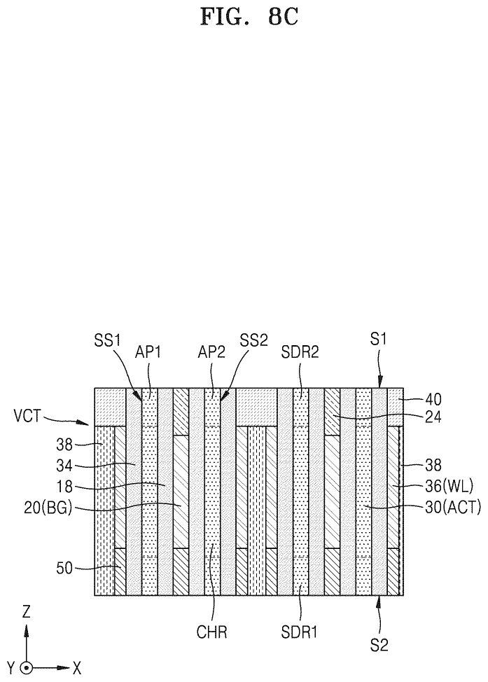

Referring to FIGS. 6A and 6B, FIG. 6B is a partially enlarged view of FIG. 6A. The semiconductor memory device may include a plurality of data storage elements DS on the second landing pads LP2. The data storage elements DS may include capacitors including lower electrodes (SP in FIGS. 8A and 8B), capacitor dielectric layers (CI in FIGS. 8A and 8B), and upper electrodes (PE in FIGS. 8A and 8B).

The data storage elements DS may be apart from one another in the first horizontal direction (X direction) and the second horizontal direction (Y direction), and may be arranged in the form of a matrix of rows and columns. The data storage elements DS may be arranged aligned with one another in the first horizontal direction (X direction) and the second horizontal direction (Y direction), respectively.

The data storage elements DS may be arranged on the first extension landing pads LP2-1 and the second extension landing pads LP2-2. From the aspect of the first row, the data storage elements DS may be arranged on the active patterns ACT, that is, the first extension landing pads LP2-1 extending (or shifted) in the first reverse horizontal direction (−X direction) on the vertical channel transistors VCT. In other words, the lower electrodes (SP in FIGS. 8A and 8B) of the first group may be arranged on the first extension landing pads LP2-1.

From the aspect of the second row, the data storage elements DS may be arranged on the active patterns ACT, that is, the second extension landing pads LP2-2 extending (or shifted) in the first horizontal direction (X direction) on the vertical channel transistors VCT. In other words, the lower electrodes (SP in FIGS. 8A and 8B) of the second group may be arranged on the second extension landing pads LP2-2. The centers of the plurality of active patterns ACT in the first and second horizontal direction (X and Y directions) may be respectively offset from the centers of the plurality of data storage elements DS, that is, the corresponding lower electrodes (SP in FIGS. 8A and 8B), among the lower electrodes (SP in FIGS. 8A and 8B).

Accordingly, the plurality of lower electrodes (SP in FIGS. 8A and 8B) may include the lower electrodes of the first group (SP in FIGS. 8A and 8B) and the lower electrodes (SP in FIGS. 8A and 8B), which are alternately arranged in the second horizontal direction (Y direction).

Odd-numbered word lines WL1, WL3, and WL5 and even-numbered word lines WL2, WL4, and WL6 of the semiconductor memory device having a layout described above may be alternately connected to the data storage elements DS, that is, the lower electrodes (SP in FIGS. 8A and 8B), on one column in the second horizontal direction (Y direction).

In other words, the odd-numbered word lines WL1, WL3, and WL5 and the even-numbered word lines WL2, WL4, and WL6 of the semiconductor memory device may be alternately connected to the data storage elements DS on one column in the second horizontal direction (Y direction). This issue is described in more detail below. As a result, the semiconductor memory device of the disclosed concepts may improve electrical reliability by improving the occurrence of leakage between the data storage elements DS arranged adjacent to one another in one row in the first horizontal direction (X direction).

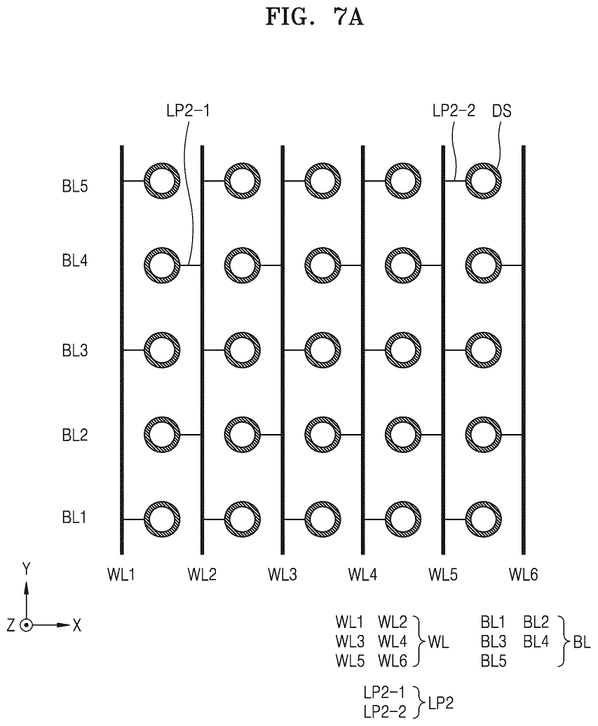

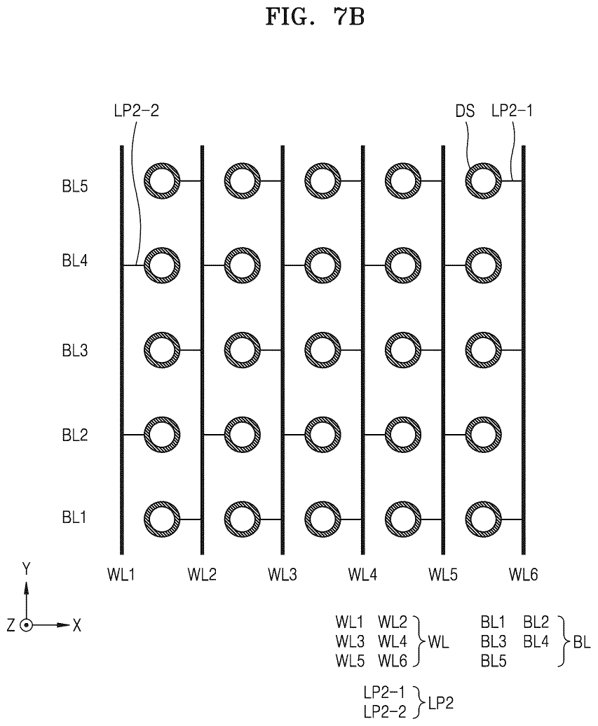

FIGS. 7A and 7B are diagrams of relations between word lines WL and data storage elements DS of the semiconductor memory device, according to embodiments.

The semiconductor memory device may include the word lines WL, the bit lines BL, the second landing pads LP2, and the data storage elements DS as described above.

The word lines WL may be spaced apart from one another in the first horizontal direction (X direction), and extend in the second horizontal direction (Y direction). The word lines WL may include the odd-numbered word lines WL1, WL3, and WL5 in the first horizontal direction (X direction). The word lines WL may include the even-numbered word lines WL2, WL4, and WL6 in the first horizontal direction (X direction). The bit lines BL may include the first through fifth bit lines BL1 through BL5.

The second landing pads LP2 may include the first extension landing pads LP2-1 extending in the first reverse horizontal direction (−X direction) and the second extension landing pads LP2-2 extending in the first horizontal direction (X direction). In FIG. 7A, the first extension landing pads LP2-1 may, as illustrated in FIG. 6A, be arranged on the second bit line BL2 and the fourth bit line BL4, and the second extension landing pads LP2-2 may be arranged on the first bit line BL1, the third bit line BL3, and the fifth bit line BL5.

In FIG. 7B, unlike as illustrated in FIG. 7A, the first extension landing pads LP2-1 may be arranged on the first bit line BL1, the third bit line BL3, and the fifth bit line BL5, and the second extension landing pads LP2-2 may be arranged on the second bit line BL2 and the fourth bit line BL4.

The data storage elements DS, that is, the lower electrodes SP in FIG. 8A and FIG. 8B, may be apart from one another in the first horizontal direction (X direction) and the second horizontal direction (Y direction), and may be arranged in the form of a matrix of rows and columns. The data storage elements DS, that is, the lower electrodes (SP in FIGS. 8A and 8B), may be arranged aligned in the first horizontal direction (X direction) and the second horizontal direction (Y direction), respectively.

As illustrated in FIGS. 7A and 7B, the odd-numbered word lines WL1, WL3, and WL5 and the even-numbered word lines WL2, WL4, and WL6 of the semiconductor memory device may be alternately connected to the data storage elements DS, that is, the lower electrodes (SP in FIGS. 8A and 8B), on one column in the second horizontal direction (Y direction).

In FIG. 7A, the odd-numbered word lines WL1, WL3, and WL5 of the semiconductor memory device may be connected to the odd-numbered data storage elements DS in one column in the second horizontal direction (Y direction), that is, the first bit line BL1, the third bit line BL3, and the fifth bit line BL5 of the data storage elements DS. In addition, the even-numbered word lines WL2, WL4, and WL6 may be connected in one column in the second horizontal direction (Y direction) to the even-numbered data storage elements DS, that is, the data storage elements DS of the second bit line B2 and the fourth bit line BL4).

In FIG. 7B, the odd-numbered word lines WL1, WL3, and WL5 of the semiconductor memory device may be connected to the even-numbered data storage elements DS, that is, the data storage elements DS of the second bit line BL2 and the fourth bit line BL4 in one column in the second horizontal direction (Y direction), and the even-numbered word lines WL2, WL4, and WL6 may be connected to the odd-numbered data storage elements DS, that is, the data storage elements DS of the first bit line BL1, the third bit line BL3, and the fifth bit line BL5 in one column in the second horizontal direction (Y direction).

FIGS. 8A and 8B are cross-sectional views of the vertical channel transistors VCT taken along lines A-A′ and B-B′ in FIG. 6A, respectively, and FIG. 8C is an enlarged view of the vertical channel transistor VCT in FIGS. 8A and 8B.

The semiconductor memory device may include the vertical channel transistors VCT formed on the bit line BL including a first conductive layer 52 and a second conductive layer 54. The vertical channel transistors VCT may include the first vertical channel transistors VCT-1 and the second vertical channel transistors VCT-2.

The vertical channel transistors VCT may include active patterns ACT 30 as illustrated in FIG. 8C. The active patterns ACT 30 may include first active patterns AP1 and second active patterns AP2. The first and second active patterns AP1 and AP2 may be alternately arranged in the first horizontal direction (X direction).

The first and second active patterns AP1 and AP2 may include first surfaces S1 and second surfaces S2 facing one another in a third direction (Z direction, a vertical direction) perpendicular to the first horizontal direction (X direction) and second horizontal direction (Y direction).

In some embodiments, the first surfaces S1 of the first and second active patterns AP1 and AP2 may be in contact with contact patterns BC 44. In some embodiments, the second surfaces S2 of the first and second active patterns AP1 and AP2 may be in contact with the bit line BL.

Each of the first and second active patterns AP1 and AP2 may have a first side surface SS1 and a second side surface SS2 facing one another in the first horizontal direction (X direction). The first side surface SS1 and the second side surface SS2 of the first active pattern AP1 may be adjacent to word lines WL 36.

Each of the first and second active patterns AP1 and AP2 may include a first source/drain region SDR1 adjacent to the bit line BL, a second source/drain region SDR2 adjacent to the contact patterns BC 44, and a channel region CHR between the first and second source/drain regions SDR1 and SDR2.

The first source/drain region SDR1 may include a first dopant region. In some embodiments, the first source/drain region SDR1 may be formed by diffusing dopants included in the first conductive layer 52 of the bit line BL during a manufacturing process. The second source/drain region SDR2 may include a second dopant region. In some embodiments, the second source/drain region SDR2 may be formed by diffusing dopants included in the contact patterns 44 during a manufacturing process.

The channel regions CHR of the first and second active patterns AP1 and AP2 may be controlled by word lines WL 36 and back gate electrodes BG 20 when the semiconductor memory device is operating. The back gate electrodes BG 20 may be arranged apart from one another at a certain interval in the first horizontal direction (X direction).

Each of the back gate electrodes BG 20 may be arranged between the first and second active patterns AP1 and AP2 adjacent to one another in the first horizontal direction (X direction). In other words, the first active pattern AP1 may be arranged on one side of each of the back gate electrodes BG 20, and the second active pattern AP2 may be arranged on the other side of each of the back gate electrode BGs 20.

The back gate electrodes BG 20 may have first surfaces (lower surfaces) close to the bit line BL and second surfaces (upper surfaces) close to the contact patterns BD 44. A negative voltage may be applied to the back gate electrodes BG 20 when the semiconductor memory device is operating, and the threshold voltage of the vertical channel transistors VCT may be increased. In other words, as the vertical channel transistors VCT become finer, the threshold voltage of the vertical channel transistors VCT may be reduced and thus deterioration of the leakage current characteristics may be prevented.

The word lines WL may be alternately arranged in the first horizontal direction (X direction). The word lines WL may be apart from the bit lines BL and the contact patterns BC 44 in the vertical direction (Z direction). In other words, the word lines WL may be between the bit lines BL and the contact patterns BC 44 in a vertical viewpoint.

Gate insulating layers 34 may be arranged between the word lines WL and the first and second active patterns AP1 and AP2. Back gate insulating layers 18 may be arranged between the back gate electrodes BG and the first and second active patterns AP1 and AP2.

First gate capping layers 24 may be formed between the back gate insulating layers 18 on upper portions of the back gate electrodes BG 20. The second gate capping layers 38 may be formed between word lines WL 36. Third gate capping layers 40 may be formed between the gate insulating layers 34. Fourth gate capping layers 50 may be formed between the back gate electrodes BG 20 under lower portions of the back gate electrodes BG 20.

The contact patterns BC 44 may be arranged on the vertical channel transistors VCT. First landing pads LP1 46 may be arranged on the contact patterns BC 44. Second landing pads LP2 58 may be arranged on the first landing pads LP1 46.

The second landing pads LP2 58 may, as illustrated in FIG. 8A, include the first extension landing pads LP2-1 extending in the first reverse horizontal direction (−X direction) on the first landing pads LP1 46. The second landing pads LP2 may, as illustrated in FIG. 8B, include the second extension landing pads LP2-2 extending in the first horizontal direction (X direction) on the first landing pads LP1 46.

The data storage elements DS may be arranged on the second landing pads LP2 58. The data storage elements DS may include capacitors including the lower electrodes SP, the capacitor dielectric layers CI, and the upper electrodes (PE in FIGS. 8A and 8B). The lower electrodes SP may be in contact with the second landing pads LP2 58.

The lower electrodes SP formed on the first extension landing pads LP2-1 may include the lower electrodes SP of the first group. The lower electrodes SP formed on the second extension landing pads LP2-2 may include the lower electrodes SP of the second group.

In the vertical direction (Z direction), the centers of the plurality of active patterns ACT may be respectively offset from centers of the corresponding lower electrodes SP among the plurality of lower electrodes SP. The bottom surface (lower surface) of each of the plurality of lower electrodes SP may partially and vertically overlap the corresponding second landing pads LP2-1 and LP2-2 among the plurality of second landing pads LP2-1 and LP2-2, but may not vertically overlap, that is, be free from the corresponding active pattern ACT among the plurality of active patterns ACT.

In FIGS. 8A and 8B, the data storage elements DS, that is, the capacitors, are illustrated as, for convenience, U-shaped lower electrodes SP, the capacitor dielectric layers CI formed inside the U-shaped lower electrodes SP, and the upper electrodes PE. However, the lower electrodes SP of the data storage elements DS, that is, the capacitors, may be formed in a pillar shape or a cylinder shape, and the capacitor dielectric layers CI may be formed both inside and outside the lower electrodes SP in the pillar shape or the cylinder shape. The data storage elements DS, that is, the capacitors, may have various structures, and accordingly, the disclosed concepts are not limited thereto.

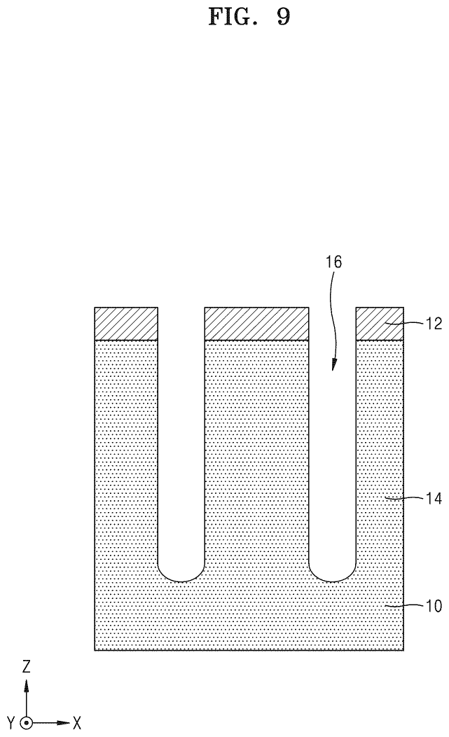

FIGS. 9 through 28 are cross-sectional views for describing a method of manufacturing a semiconductor memory device, according to embodiments.

Referring to FIG. 9, a plurality of first mask patterns 12 are formed on the substrate 10. The substrate 10 may include a silicon substrate, a germanium substrate, or a silicon-germanium substrate. The first mask patterns 12 may include silicon nitride.

A plurality of first trenches 16 may be formed in the substrate 10 by etching the substrate 10 with the first mask patterns 12 as an etching mask. The first trenches 16 may include trenches for forming back gate electrodes BG. Active regions 14 may be formed in the substrate 10 according to the formation of the first trenches 16.

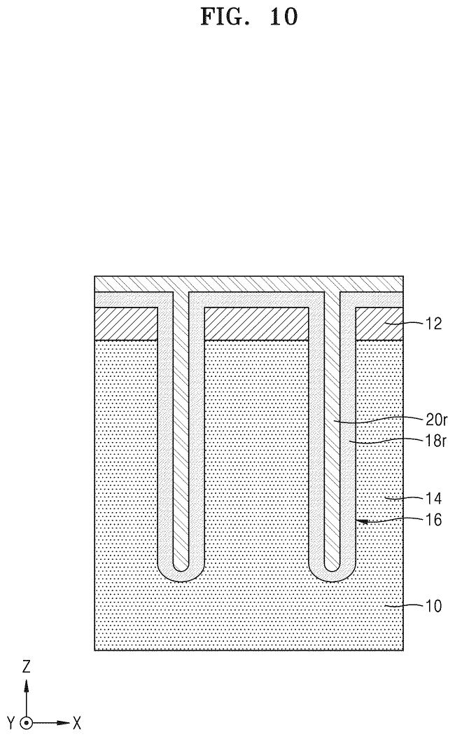

Referring to FIG. 10, a back gate insulating material layer 18r may be formed inside the first trenches 16 and on the first mask patterns 12. The back gate insulating material layer 18r may include a silicon oxide layer, a silicon oxynitride layer, a high dielectric layer with a higher dielectric constant than the silicon oxide layer, or a combination thereof.

A back gate electrode material layer 20r may be formed on the back gate insulating material layer 18r to fill the first trenches 16. The back gate electrode material layer 20r may include doped polysilicon, conductive metal nitride (for example, titanium nitride, tantalum nitride, etc.), a metal (for example, tungsten, titanium, tantalum, etc.), conductive metal silicide, conductive metal oxide, or a combination thereof.

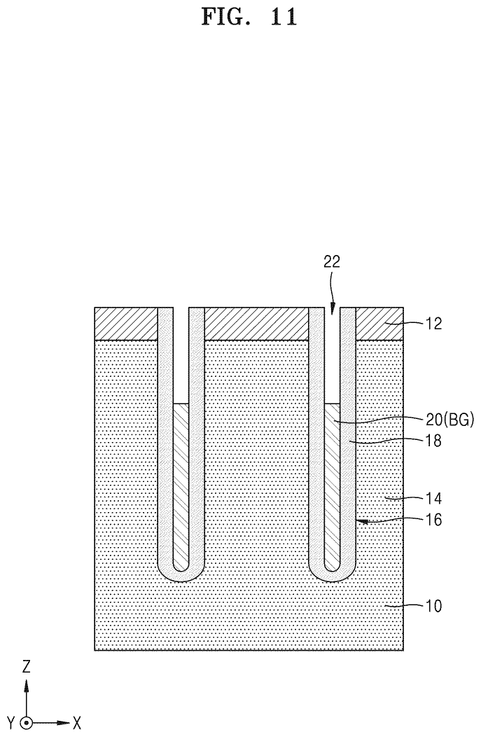

Referring to FIG. 11, a plurality of back gate electrodes 20 may be respectively formed in the first trenches 16 by etchbacking the back gate electrode material layer 20r. The back gate electrodes 20 may be formed to be lower than upper surfaces of the first trenches 16. First recess holes 22 may be formed in the back gate electrodes 20 when the back gate electrode material layer 20r is etchbacked.

The back gate electrodes 20 may constitute the back gate electrodes BG in FIG. 6A by using subsequent processes. While the back gate electrode material layer 20r is etchbacked, the back gate insulating material layer 18r on the first mask patterns 12 may also be etchbacked, and the back gate insulating layers 18 may be formed on internal walls of the first trenches 16.

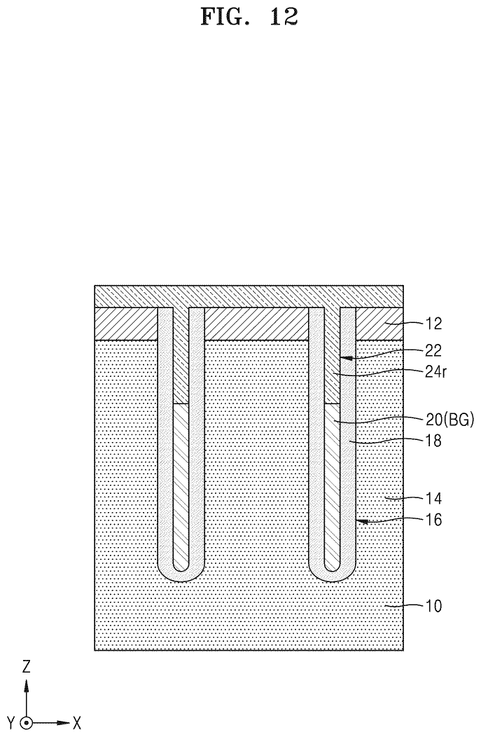

Referring to FIG. 12, a first gate capping material layer 24r may be formed to fill the first recess holes 22 on the back gate insulating layers 18 and on the first mask patterns 12 in the first trenches 16. The first gate capping material layer 24r may include silicon oxide or silicon nitride.

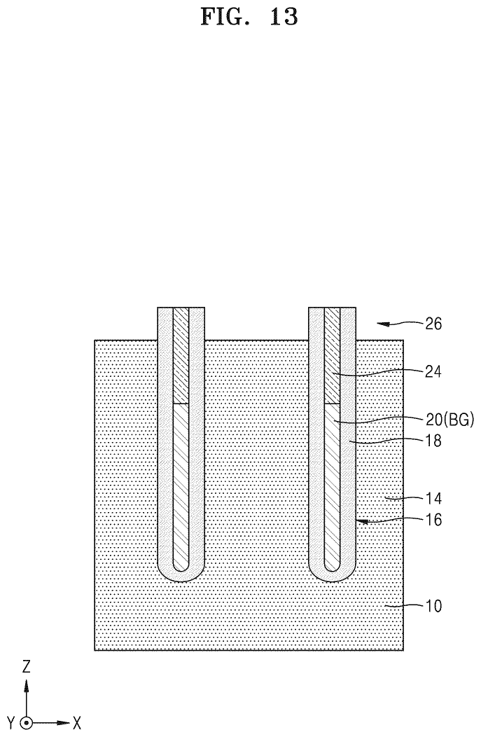

Referring to FIG. 13, by etchbacking the first gate capping material layer 24r, the first gate capping layers 24 may be respectively formed in the first recess holes 22. Subsequently, the first mask patterns (12 in FIG. 12) may be removed. As a result, upper portions 26 of the back gate insulating layers 18 and the first gate capping layers 24 may be formed higher than upper surfaces of the active regions 14.

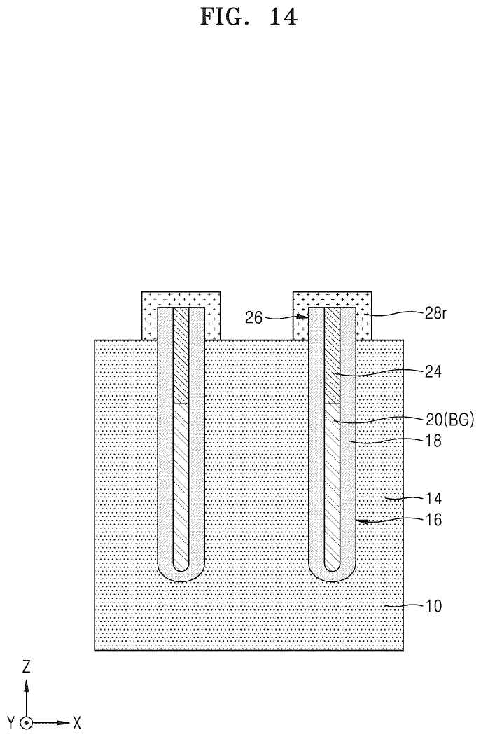

Referring to FIG. 14, spacer material layers 28r may be formed on the active regions 14 to cover the upper portions (26 in FIG. 13) of the back gate insulating layers 18 and the first gate capping layers 24. The spacer material layers 28r may be formed on both sidewalls and upper surfaces of the back gate insulating layers 18 and the first gate capping layers 24. The width of the active patterns 30 to be subsequently processed may be determined according to the deposition thickness of the spacer material layers 28r.

The spacer material layers 28r may include an insulating material. The spacer material layers 28r may include silicon oxide, silicon oxynitride, silicon nitride, silicon carbide (SiC), silicon carbon nitride (SiCN), or a combination thereof.

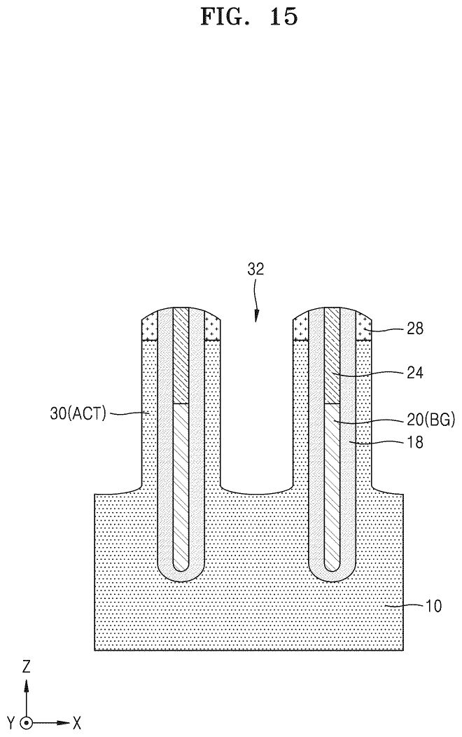

Referring to FIG. 15, the plurality of active patterns 30 may be formed by anisotropically etching the spacer material layers (28 in FIG. 14) with the active region (14 in FIG. 14) as the etching mask. When the active patterns 30 are formed, the spacer material layers (28 in FIG. 14) may be the spacers 28. The active patterns 30 may correspond to the active patterns ACT in FIG. 6A by using subsequent processes.

The active patterns 30 may be formed on both sides of the back gate insulating layers 18. Second trenches 32 may be formed between the active patterns 30 adjacent to one another in the first horizontal direction (X direction). One sidewall of the active pattern 30 may be exposed by the second trench 32.

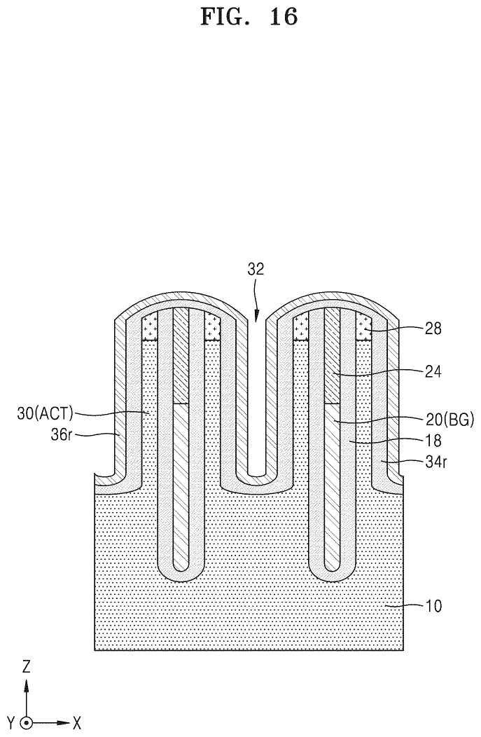

Referring to FIG. 16, a gate insulating material layer 34r conformally covering sidewalls of the active patterns 30 and upper surfaces of the first gate capping layers 24 may be formed. The gate insulating material layer 34r may include a silicon oxide layer, a silicon oxynitride layer, a high dielectric layer with a higher dielectric constant than the silicon oxide layer, or a combination thereof.

The gate insulating material layer 34r may be formed by using at least one of physical vapor deposition (PVD), thermal chemical vapor deposition (CVD), low pressure (LP) CVD (LP-CVD), plasma enhanced (PE) CVD (PE-CVD), or atomic layer deposition (ALD).

A gate electrode material layer 36r is formed on the gate insulating material layer 34r. The gate electrode material layer 36r may include doped polysilicon, conductive metal nitride (for example, titanium nitride, tantalum nitride, etc.), a metal (for example, tungsten, titanium, tantalum, etc.), conductive metal silicide, conductive metal oxide, or a combination thereof. The gate electrode material layer 36r may become a gate electrode (word line) by using subsequent processes.

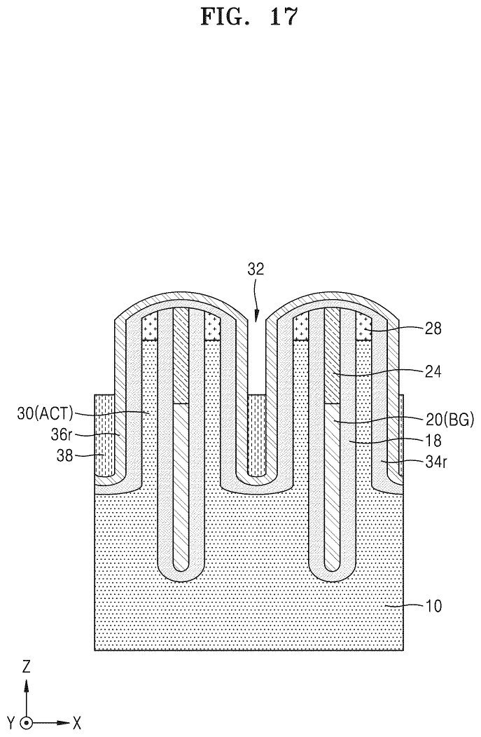

Referring to FIG. 17, second gate capping layers 38 may be formed on sidewalls of the gate electrode material layers 36r on sidewalls of the active patterns 30 and on sidewalls of the gate electrode material layers 36r in the second trenches 32. The second gate capping layers 38 may be formed by forming a second gate capping insulating layer on the gate insulating material layer 34r and then etchbacking. The second gate capping layer 38 may include silicon oxide or silicon nitride.

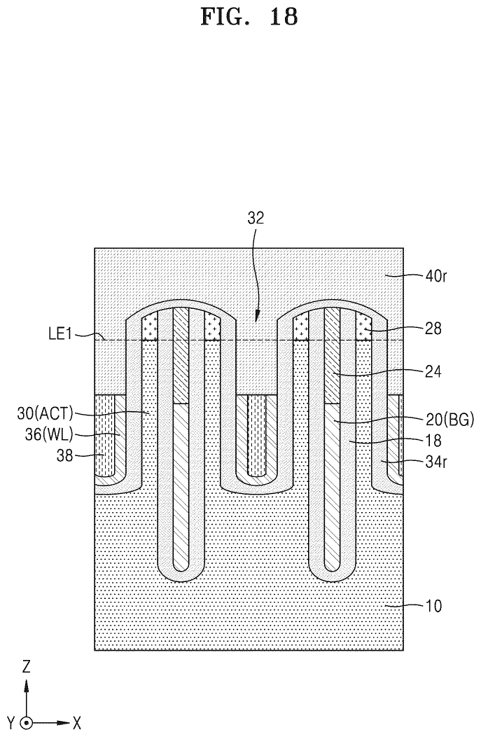

Referring to FIG. 18, a plurality of gate electrodes 36 may be formed by etchbacking the gate electrode material layer 36r. The gate electrodes 36 may become the word line WL by using subsequent processes. The gate electrodes 36 may have the same plane as surfaces of the second gate capping layers 38.

A third gate capping material layer 40r may be formed to fill the second trenches 32 and on the gate insulating material layer 34r, the gate electrodes 36, and the second gate capping layers 38. The third gate capping material layer 40r may include silicon oxide or silicon nitride.

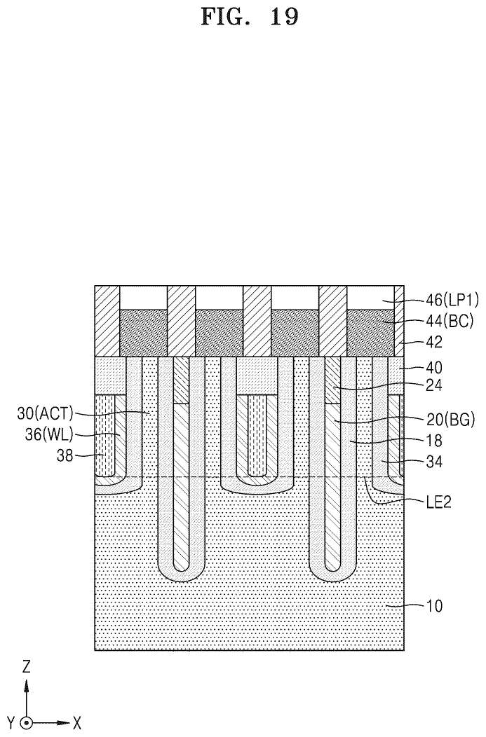

Referring to FIG. 19, upper portions of the back gate insulating layers 18, the first gate capping layers 24, the active patterns 30, the gate insulating material layer 34r, and the third gate capping material layer 40r may be etchbacked and planarized according to a first level (LE1 in FIG. 18), which is the lower surface of the spacers (28 in FIG. 18).

In this manner, as illustrated in FIG. 19, the spacers (28 in FIG. 18) may be removed. The gate insulating material layer 34r and the third gate capping material layer 40r may become the gate insulating layers 34 and the third gate capping layers 40, respectively. Upper surfaces of the back gate insulating layers 18, the first gate capping layers 24, and the active patterns 30 may be coplanar.

Subsequently, the contact patterns 44 and the first landing pads 46 may be formed on the active patterns 30. The contact patterns 44 and the first landing pads 46 may be insulated by first interlayer insulating patterns 42. The contact patterns 44 may correspond to the contact patterns BC in FIG. 6A. The first landing pads 46 may correspond to the first landing pads LP1 in FIG. 6A.

In some embodiments, the contact patterns 44 may be formed by using polysilicon doped with impurities. In some embodiments, the contact patterns 44 may include Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof.

The first landing pads 46 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or a combination thereof.

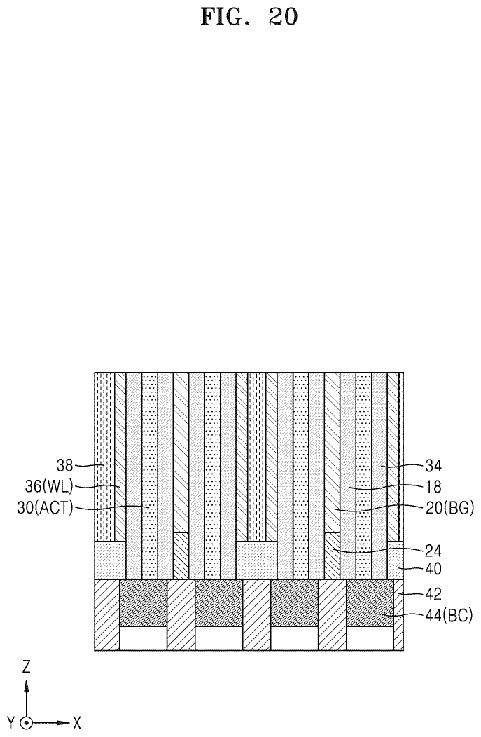

Referring to FIG. 20, after inverting the resultant product of FIG. 19, upper portions of the back gate insulating layers 18, the back gate electrodes 20, the active patterns 30, the gate insulating layers 34, the gate electrodes 36, and lower portions of the substrate 10 may be etchbacked and planarized according to a second level (LE2 in FIG. 19), which is the upper surface of the second gate capping layer (38 in FIG. 19).

As a result, surfaces of the back gate insulating layers 18, the back gate electrodes 20, the active patterns 30, the gate insulating layers 34, the gate electrodes 36, and the second gate capping layers 38 may be coplanar.

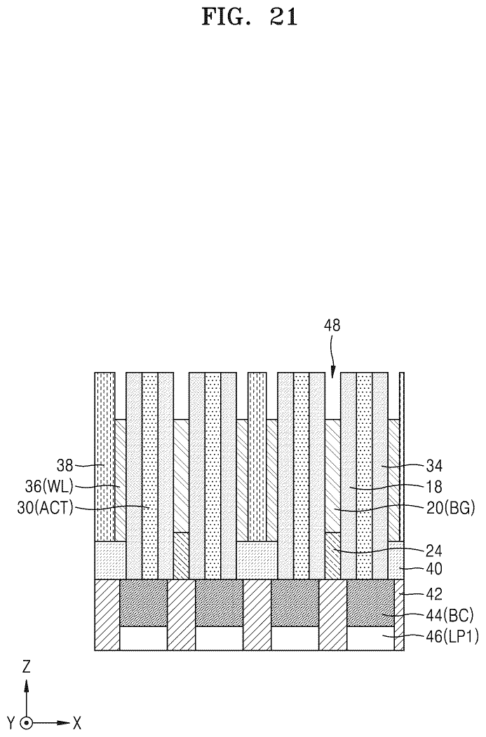

Referring to FIGS. 21 through 23, as illustrated in FIG. 21, by selectively etchbacking the gate electrodes 36 and the back gate electrodes 20, a plurality of second recess holes 48 may be formed. The second recess holes 48 may be formed between each of the back gate insulating layers 18, and between the back gate insulating layers 18 and the second gate capping layers 38.

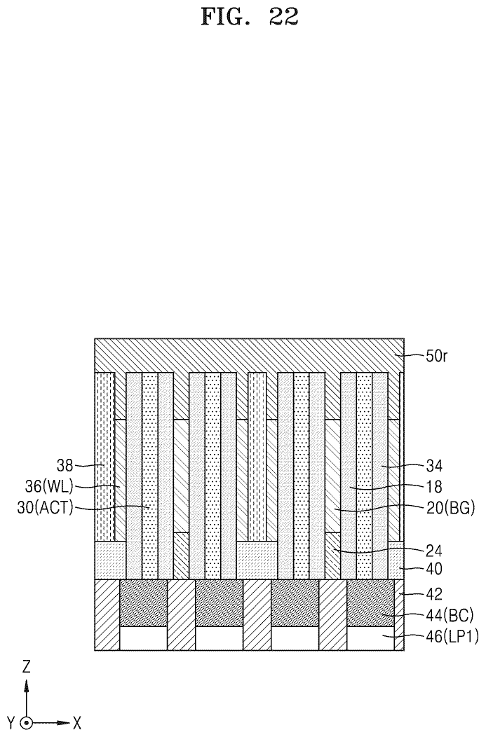

As illustrated in FIG. 22, a fourth gate capping material layer 50r may be formed to cover the back gate insulating layers 18, the back gate electrodes 20, the active patterns 30, the gate insulating layers 34, the gate electrodes 36, and the second gate capping layers 38, to fill the second recess holes 48. The fourth gate capping material layer 50r may include silicon oxide or silicon nitride.

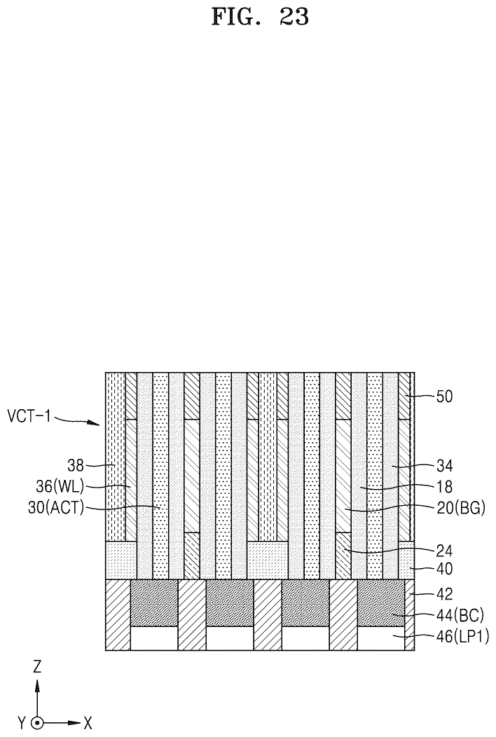

As illustrated in FIG. 23, by etchbacking the fourth gate capping material layer 50r, the fourth gate capping layers 50 may be formed in the second recess holes 48. The fourth gate capping layers 50 may be formed between each of the back gate insulating layers 18, and between the back gate insulating layers 18 and the second gate capping layers 38.

By using the processes described above, the first vertical channel transistors VCT-1 of FIG. 8A may be formed. The first vertical channel transistors VCT-1 of FIG. 23 have been described in detail with reference to FIG. 8C, and thus descriptions thereof are omitted herein.

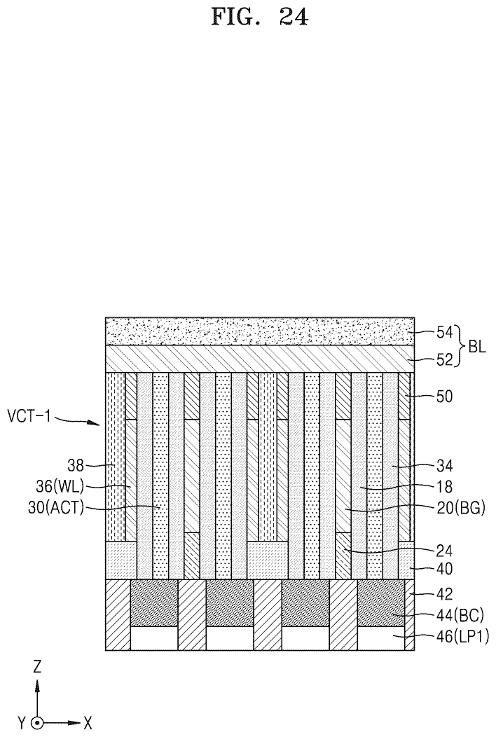

Referring to FIG. 24, the first conductive layer 52 and the second conductive layer 54 may be sequentially formed on the back gate insulating layers 18, the back gate electrodes 20, the active patterns 30, the gate insulating layers 34, the gate electrodes 36, and the fourth gate capping material layers 50.

The first conductive layer 52 may include polysilicon doped with impurities. The second conductive layer 54 may include a metal layer. The second conductive layer 54 may include conductive metal nitride (for example, titanium nitride, tantalum nitride, etc.) and a metal (for example, tungsten, titanium, tantalum, etc.). The first conductive layer 52 and the second conductive layer 54 may correspond to the bit line BL in FIG. 6A.

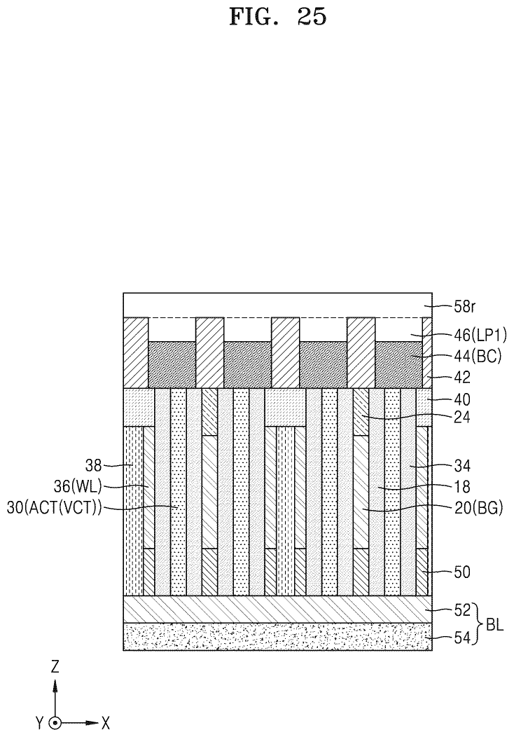

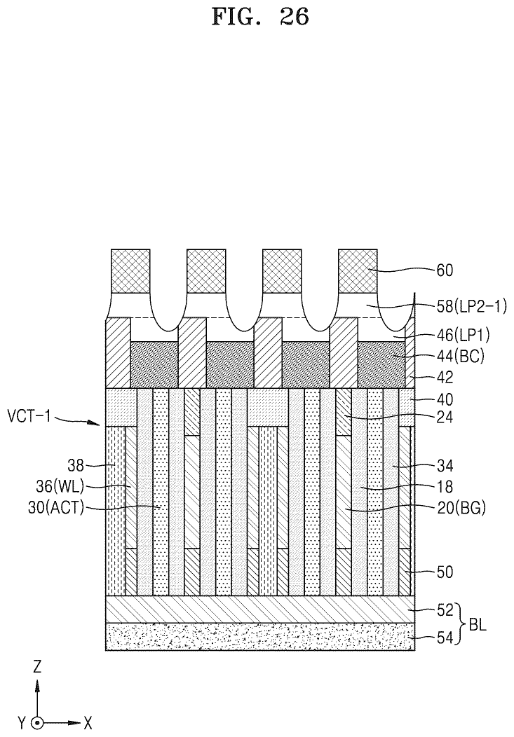

Referring to FIGS. 25 and 26, a plurality of second landing pads 58 shifted in the first reverse horizontal direction (−X direction) may be formed on the first landing pads 46. The second landing pads 58 may extend on the first landing pads 46 in the first reverse horizontal direction (−X direction). The second landing pads 58 may correspond to the first extension landing pads LP2-1 extending in the first reverse horizontal direction (−X direction) in FIG. 6A.

The second landing pads 58 may be formed by forming the second landing pad material layer 58r on the first landing pads 46, forming a plurality of second mask patterns 60 on the second landing pad material layer 58r, and etching the second landing pad material layer 58r with the second mask patterns 60 as an etching mask. The second mask patterns 60 may be formed by being shifted on the first landing pads LP1 in the first reverse horizontal direction (−X direction) and by using a photo-etching process.

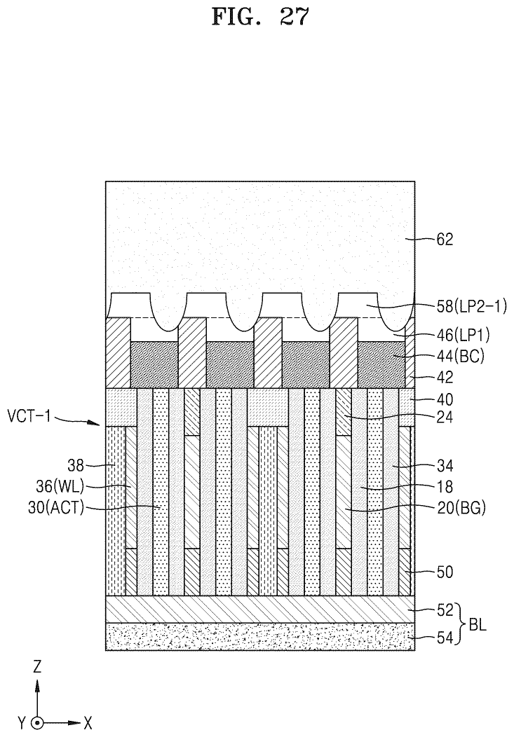

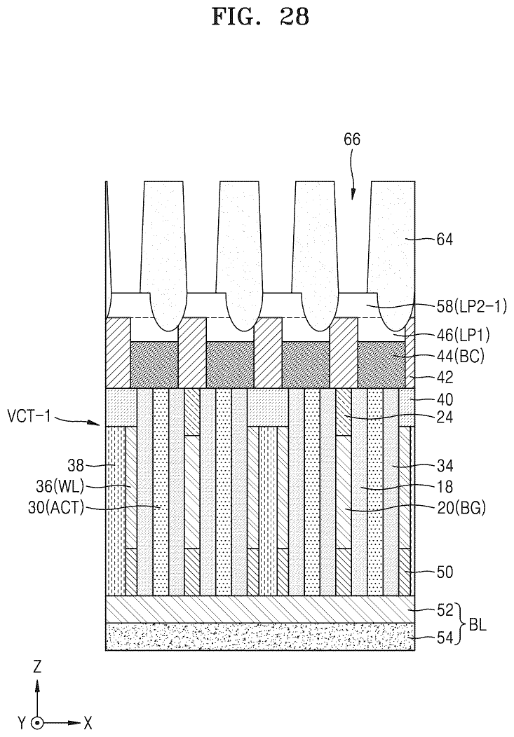

Referring to FIGS. 27 and 28, a second interlayer insulating layer 62 may be formed on the second landing pads 58, after the second mask patterns (60 in FIG. 26) is removed as illustrated in FIG. 27. The second interlayer insulating layer 62 may be formed by using a silicon oxide layer or a silicon nitride layer.

As illustrated in FIG. 28, by etching the second interlayer insulating layer 62, a plurality of contact holes 66 respectively exposing the second landing pads 58. The second interlayer insulating layer 62 may become a plurality of second interlayer insulating patterns 64 according to the formation of the contact holes 66. Subsequently, as illustrated in FIG. 7, by forming the data storage elements DS in the contact holes 66, the semiconductor memory device may be completely manufactured.

A semiconductor memory device of the technical idea of the disclosed concepts may shift landing pads electrically connected to vertical channel transistors, connect respectively data storage elements in one column to different word lines, and control the devices. Accordingly, the semiconductor memory device of the technical idea of the disclosed concepts may improve electrical reliability by improving the occurrence of linkage between the data storage elements arranged adjacent to one another in one row.

While the disclosed concepts have been particularly shown and described with reference to example embodiments thereof, it will be understood by one of ordinary skill in the art that various modifications, permutations, and other equivalent embodiments may be made therein without departing from the spirit and scope of the disclosed concepts as defined by the following claims. It should be understood that the above-described embodiments are illustrative and non-restrictive in every respect. Accordingly, the true scope of protection of the disclosed concepts should be determined by the technical idea of the following claims.

What is claimed is:

1. A semiconductor memory device comprising:
a plurality of active patterns arranged apart from one another in a first substantially horizontal direction and in a second substantially horizontal direction perpendicular to the first substantially horizontal direction, and arranged in a matrix form of rows and columns;
a plurality of landing pads respectively arranged on the plurality of active patterns and apart from one another in the first and second substantially horizontal directions, wherein the plurality of landing pads include the landing pads, of a first group, shifted in a first reverse substantially horizontal direction on the active patterns forming one column among the plurality of active patterns and the landing pads, of a second group, shifted in the first substantially horizontal direction;
a plurality of lower electrodes respectively arranged on the plurality of landing pads and apart from one another in the first and second substantially horizontal directions; and
a plurality of word lines respectively arranged on one side of the plurality of active patterns, apart from one another in the first substantially horizontal direction, and extending in the second substantially horizontal direction,
wherein the plurality of word lines comprise odd-numbered word lines and even-numbered word lines in the first substantially horizontal direction, and the odd-numbered word lines and the even-numbered word lines are alternately connected to the landing pads of the first group and the landing pads of the second group in one column in the second substantially horizontal direction, respectively.

2. The semiconductor memory device of claim 1, wherein each of the plurality of active patterns comprises a first source/drain region and a second source/drain region arranged in a substantially vertical direction, and a channel region between the first and second source/drain regions.

3. The semiconductor memory device of claim 1, wherein a plurality of lower electrodes comprise the lower electrodes of a first group and the lower electrodes of a second group alternately arranged in the second substantially horizontal direction, and
wherein the lower electrodes of the first group are connected to one of the odd-numbered word lines, and the lower electrodes of the second group are connected to one of the even-numbered word lines.

4. The semiconductor memory device of claim 1, wherein centers of the plurality of active patterns are offset from a center of the corresponding lower electrode among the plurality of lower electrodes.

5. The semiconductor memory device of claim 1, wherein a lower surface of each of the plurality of lower electrodes partially and vertically overlaps the corresponding landing pad among the plurality of landing pads, but does not vertically overlap the corresponding active pattern, that is, is free from the corresponding active pattern among the plurality of active patterns.

6. The semiconductor memory device of claim 1, further comprising a back gate electrode extending in the second substantially horizontal direction between one of the odd-numbered word lines and one of the even-numbered word lines.

7. The semiconductor memory device of claim 1, wherein the plurality of lower electrodes comprise the lower electrodes of a first group and the lower electrodes of a second group alternately arranged in the second substantially horizontal direction, and
wherein the lower electrodes of the first group are connected to one of the even-numbered word lines, and the lower electrodes of the second group are connected to one of the odd-numbered word lines.

8. The semiconductor memory device of claim 1, wherein a plurality of bit lines extending in the first substantially horizontal direction and apart from one another in the second substantially horizontal direction are further arranged on lower portions of the active patterns and the plurality of word lines.

9. A semiconductor memory device comprising:
a plurality of active patterns arranged apart from one another in a first substantially horizontal direction and in a second substantially horizontal direction perpendicular to the first substantially horizontal direction, and arranged in a matrix form of rows and columns;
a plurality of landing pads arranged on the active patterns and apart from one another in the first and second substantially horizontal directions, wherein the landing pads comprise first landing pads on the active patterns, second landing pads of a first group shifted in a first reverse substantially horizontal direction on the first landing pads arranged on the active patterns forming one column among the plurality of active patterns, and second landing pads of a second group shifted in the first substantially horizontal direction;
a plurality of lower electrodes respectively arranged on the second landing pads of the first group and the second landing pads of the second group, and apart from one another in the first and second direction; and
a plurality of word lines respectively arranged on one side of the plurality of active patterns, apart from one another in the first substantially horizontal direction, and extending in the second substantially horizontal direction,
wherein the plurality of word lines comprise odd-numbered word lines and even-numbered word lines in the first substantially horizontal direction, the odd-numbered word lines and the even-numbered word lines are alternately connected to the second landing pads of the first group and the second landing pads of the second group in one column in the second substantially horizontal direction, respectively.

10. The semiconductor memory device of claim 9, wherein the plurality of lower electrodes comprise the lower electrodes of a first group and the lower electrodes of a second group alternately arranged in the second substantially horizontal direction, and
wherein the lower electrodes of the first group are connected to one of the odd-numbered word lines, and the lower electrodes of the second group are connected to one of the even-numbered word lines.

11. The semiconductor memory device of claim 9, wherein the plurality of lower electrodes comprise the lower electrodes of a first group and the lower electrodes of a second group alternately arranged in the second substantially horizontal direction, and
wherein the lower electrodes of the first group are connected to one of the even-numbered word lines, and the lower electrodes of the second group are connected to one of the odd-numbered word lines.

12. The semiconductor memory device of claim 9, wherein the second landing pads comprise first extension landing pads extending in a first reverse substantially horizontal direction and second extension landing pads extending in the first substantially horizontal direction on the active patterns of the one column, and
wherein the first extension landing pads and the second extension landing pads are alternately arranged on the active patterns of the one column.

13. The semiconductor memory device of claim 9, wherein the odd-numbered word lines comprise a first word line, a third word line, and a fifth word line in the fifth substantially horizontal direction, the even-numbered word lines comprise a second word line facing the first word line, a fourth word line facing the third word line, and a sixth word line facing the fifth word line.

14. The semiconductor memory device of claim 13, further comprising back gate electrodes extending in the second substantially horizontal direction between the second word line and the third word line, and between the fourth word line and the fifth word line.

15. The semiconductor memory device of claim 9, wherein each of the plurality of active patterns comprises a first source/drain region and a second source/drain region arranged in a substantially vertical direction, and a channel region between the first and second source/drain regions.

16. The semiconductor memory device of claim 9, wherein a plurality of bit lines extending in the first substantially horizontal direction and apart from one another in the second substantially horizontal direction are further arranged on lower portions of the plurality of lower electrodes and the word lines.

17. A semiconductor memory device comprising:
a plurality of bit lines extending in a first substantially horizontal direction and apart from one another in a second substantially horizontal direction perpendicular to the first substantially horizontal direction;
a plurality of word lines on the bit lines, wherein the word lines extend in the second substantially horizontal direction and are apart from one another in the first substantially horizontal direction;
a plurality of active patterns apart from one another on one side of the word lines on the bit lines in the first substantially horizontal direction and the second substantially horizontal direction, and arranged in a matrix form of rows and columns;
a plurality of landing pads arranged on the active patterns and apart from one another in the first and second substantially horizontal directions, wherein the landing pads comprise first landing pads on the active patterns, second landing pads of a first group shifted in a first reverse substantially horizontal direction on the first landing pads arranged on the active patterns forming one column among the plurality of active patterns, and second landing pads of a second group shifted in the first substantially horizontal direction;
a plurality of lower electrodes respectively arranged on the second landing pads of the first group and the second landing pads of the second group, and apart from one another in the first and second direction; and
a plurality of word lines respectively arranged on one side of the plurality of active patterns, apart from one another in the first substantially horizontal direction, and extending in the second substantially horizontal direction,
wherein a lower surface of each of the plurality of lower electrodes partially and vertically overlaps the corresponding second landing pad among the plurality of second landing pads, but does not vertically overlap, that is, is free from the corresponding active pattern among the plurality of active patterns,
wherein the plurality of word lines comprise odd-numbered word lines and even-numbered word lines in the first substantially horizontal direction, the odd-numbered word lines and the even-numbered word lines are alternately connected to the second landing pads of the first group and the second landing pads of the second group in one column in the second substantially horizontal direction, respectively.

18. The semiconductor memory device of claim 17, wherein the plurality of lower electrodes comprise the lower electrodes of a first group and the lower electrodes of a second group alternately arranged in the second substantially horizontal direction, and
wherein the lower electrodes of the first group are connected to one of the even-numbered word lines, and the lower electrodes of the second group are connected to one of the odd-numbered word lines.

19. The semiconductor memory device of claim 17, wherein centers of the plurality of active patterns are offset from a center of the corresponding lower electrode among the plurality of lower electrodes.

20. The semiconductor memory device of claim 17, further comprising a back gate electrode extending in the second substantially horizontal direction between one of the odd-numbered word lines and one of the even-numbered word lines.
